(19) United States
(12) Patent Application Publication
(10) Pub. No.: US 2007/0063192 A1
(43) Pub. Date: Mar. 22, 2007

(54) Systems for emitting light incorporating pixel structures of organic light-emitting diodes

(75) Inventor: Du-Zen Peng, Chubei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Toppoly Optoelectronics Corp.

(21) Appl. No.: 11/230,432

(22) Filed: Sep. 20, 2005

(51) Int. Cl. H01L 29/08

(52) U.S. Cl. 257/40

(57) ABSTRACT

Systems for emitting light incorporating pixel structures of organic light-emitting diodes (OLEDs) are provided. A representative system comprises: a first sub-pixel area including a first OLED; and a second sub-pixel area including a second OLED and a second control circuit, wherein said second control circuit includes electronic components for controlling said first and second OLEDs.

### BACKGROUND OF THE INVENTION

1. Field of the Invention

The present invention relates to organic light-emitting diodes (OLEDs).

2. Description of the Related Art

An organic light-emitting diode (OLED) display is a flat display capable of emitting a light in which an organic compound is employed as a lighting material. An OLED display may provide advantages of compactness, slightness, a wide viewing angle, a high contrast, and a high response speed, among others.

Referring to FIG. 1, a sub-pixel of a conventional OLED display is schematically depicted. The OLED display comprises a plurality of pixels, each comprising a plurality of sub-pixel areas 11. A power line 12, a data line 13 and a scan line 14 are shown. The sub-pixel area 11 includes a light-emitting area 15 and a non-light-emitting area 16.

The light-emitting area 15 comprises an OLED formed with an organic compound film through which electrical energy (provided by the power line) is transformed into light energy. he non-light-emitting area 16 has a control circuit (not shown) for controlling the OLED in the light-emitting area 15.

The control circuit typically comprises diodes, transistors, capacitors and other electronic components. Since the non-light-emitting area 16 does not emit any light, it is desired to have a smaller area thereof. The ratio of the area of the light-emitting area 15 to the area of the sub-pixel area 11 is called the “aperture ratio.” Thus, a higher aperture ratio corresponds to higher luminance.

Referring to FIG. 2A, a prior pixel structure of a typical full-color OLED display is schematically depicted. In the full-color OLED display, each pixel comprises a red sub-pixel area 17, a green sub-pixel area 18 and a blue sub-pixel area 19. In the red sub-pixel area 17, a light-emitting area 20 has an R-OLED and a non-light-emitting area 21 has a control circuit for the R-OLED. In the green and blue sub-pixel areas 18, 19, similar structures as that set forth in the red sub-pixel area 17 are provided.

By virtue of the control circuits of the sub-pixel areas 17, 18, 19, the luminance of the OLEDs may be controlled to achieve full color image display. Since light emission efficiency of the presently available red, green, and blue OLEDs is not identical and since the light-emitting areas corresponding thereto are generally the same, the OLED of poorer light emission efficiency has to be supplied with larger electric energy so as to have the same luminance as that of the other OLEDs.

Referring to FIG. 2B, another prior pixel structure of a typical full-color OLED display is schematically depicted. In this full-color OLED display, each pixel comprises a red sub-pixel area 22, a green sub-pixel area 23, a blue sub-pixel area 24 and a white sub-pixel area 25. In the white sub-pixel area 25, a light-emitting area 26 has a W-OLED and a non-light-emitting area 27 has a control circuit for the W-OLED.

In FIG. 2A, if a white image is desired to be displayed, illumination from red, green, and blue sub-pixels 17, 18, and 19 should be combined. However, in FIG. 2B, if a white image is desired to be displayed, only the white sub-pixel 25 is required to emit that is, the red, green, and blue sub-pixels 22, 23, and 24 need not emit. Therefore, the RGBW OLED display of FIG. 2B typically requires less power consumption than the RGB OLED display of FIG. 2A when a white image is displayed. However, since the control circuits in the non-light-emitting areas must accommodate a fixed area, the RGBW OLED display of FIG. 2B suffers from having smaller light-emitting area, that is, a lower aperture ratio than the aperture ratio of the RGB OLED display of FIG. 2A.

### SUMMARY OF THE INVENTION

The present invention provides systems for emitting light. An embodiment of such a system comprises a pixel structure of an organic light-emitting diode (OLED). The pixel structure comprises: a first sub-pixel area including a first OLED; and a second sub-pixel area including a second OLED and a second control circuit, wherein said second control circuit includes electronic components for controlling said first and second OLEDs.

In another embodiment of such a system, the pixel structure of an organic light-emitting diode (OLED) comprises a blue sub-pixel area including a blue OLED, and a white sub-pixel area including a white OLED and a second control circuit. The second control circuit includes electronic components for controlling the blue and white OLEDs. The blue sub-pixel area can include no electronic components.

### BRIEF DESCRIPTION OF THE DRAWINGS

The invention will become more fully understood from the detailed description given below for illustration only. The embodiments described are not limitative of the present invention. In the drawings:

FIG. 1 illustrates schematically a prior sub-pixel structure of organic light-emitting diode (OLED) display;

FIG. 2A illustrates schematically a prior pixel structure of a full-color organic light-emitting diode (OLED) display;

FIG. 2B illustrates schematically another prior pixel structure of a full-color organic light-emitting diode (OLED) display;

FIG. 3 illustrates schematically a pixel structure of a first of embodiment an OLED display;

FIG. 4 illustrates schematically an embodiment of a control circuit for a pixel structure of an OLED display;

FIG. 5 illustrates schematically a pixel structure of a second embodiment of an OLED display;

FIG. 6 illustrates schematically the control circuit for pixel structure of the OLED display of FIG. 5;

FIG. 7 illustrates schematically a third embodiment of a pixel structure of OLED display.

FIG. 8 illustrates schematically an embodiment of a display device; and

FIG. 9 illustrates schematically an embodiment of an electronic device.

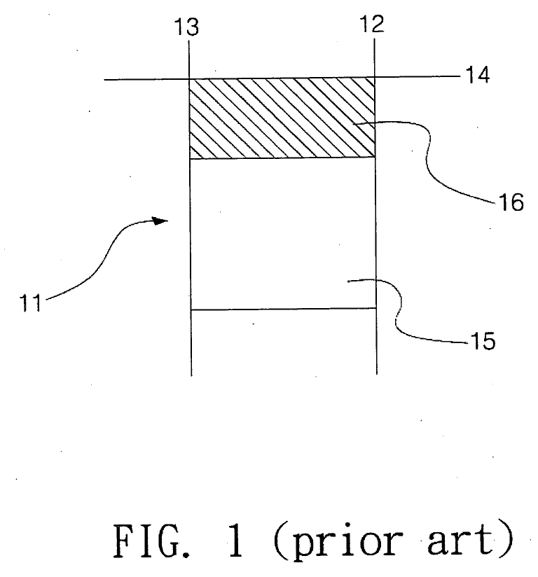

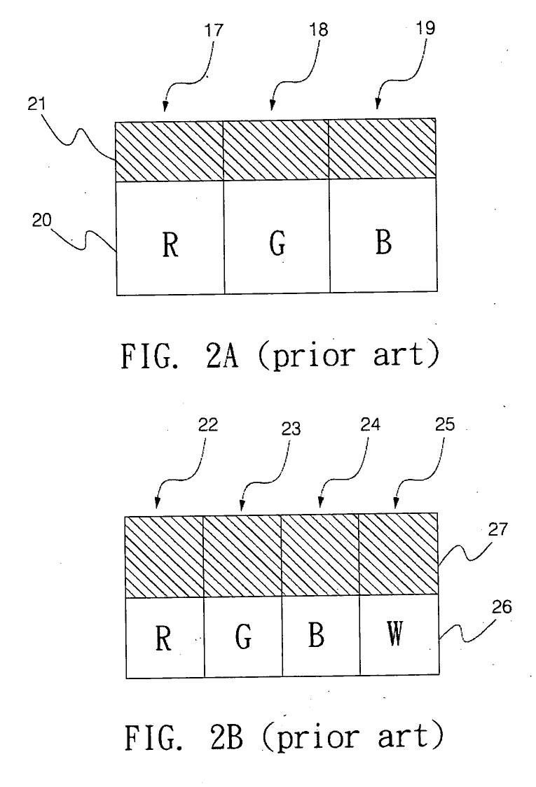

### DETAILED DESCRIPTION

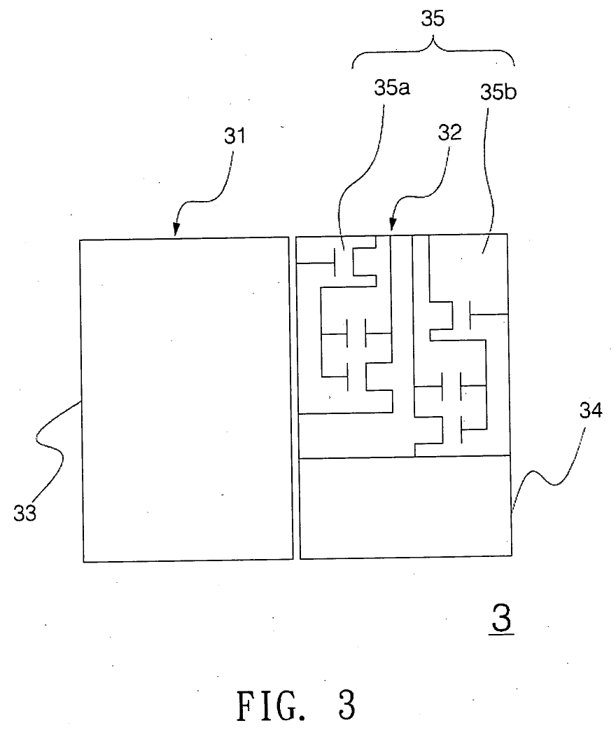

Referring to FIG. 3, a first embodiment of a pixel structure of an organic light-emitting diode (OLED) display-is depicted schematically. The pixel structure 3 of the OLED display comprises: a first sub-pixel area 31 and a second sub-pixel area 32. The first sub-pixel area 31 includes a first OLED 33, but does not include a control circuit. The second sub-pixel area 32 includes a second OLED 34 and a control circuit 35. The control circuit 35 includes a first control circuit portion 35a, and a second control circuit portion 35b. The first control circuit portion 35a includes electronic components for controlling the first OLED 33, and the second control circuit portion 35b includes electronic components for controlling the second OLED 34.

In this embodiment, the light emission efficiency of the first OLED 33 can be lower than that of the second OLED 34. For example, the first OLED 33 can be a blue OLED and the second OLED 34 can be a red, green or white OLED. Since the first control circuit portion 35a for controlling the first OLED 33 is disposed in the second sub-pixel area 32, but not in the first sub-pixel area 31, the area of the first OLED 33 may be increased as compared to that used in the prior art. This potentially enables brightness and lifetime of the first OLED 33 resident in the first sub-pixel area 31 to be improved.

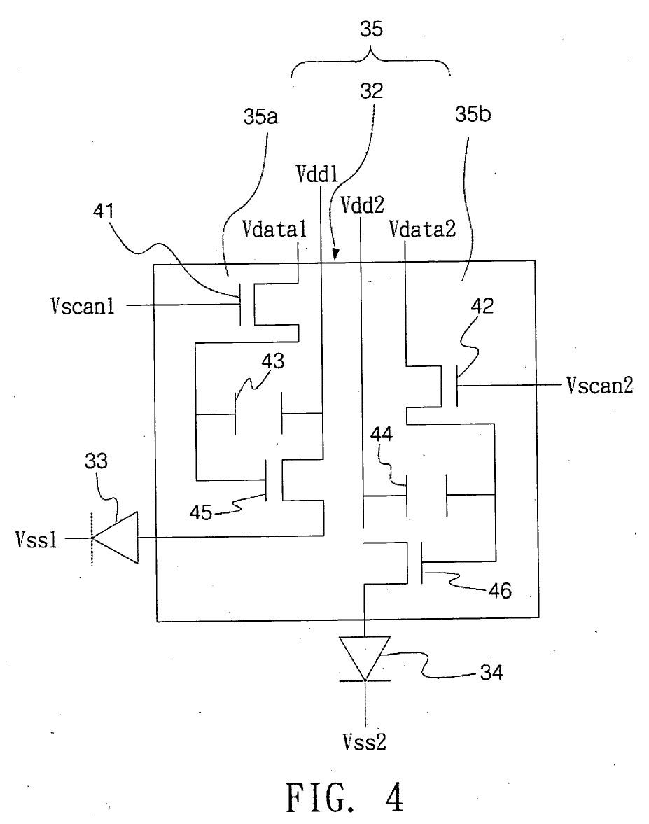

Referring to FIG. 4, a first embodiment of a control circuit 35 for the pixel 3 of the OLED display is depicted schematically. As mentioned above, both of the control circuit portions 35a and 35b are disposed in the second sub-pixel area 32. The first control circuit portion 35a comprises a first switch transistor 41, a first capacitor 43, and a first driving transistor 45 that are used for controlling the first OLED 33. The second control circuit portion 35b comprises a second switch transistor 42, a second capacitor 44, and a second driving transistor 46, that which are used for controlling the second OLED 34.

When a signal Vscan1 on a scan line is transmitted to the gate of the first switch transistor 41, a signal Vdata1 on a data line is taken and stored in the first capacitor 43 through the first switch transistor 41 and turns on the first driving transistor 45. The first driving transistor 45 is connected to a power line having a voltage level of Vdd1 and the first OLED 33, and thereby provides a driving current to the first OLED 33. The first OLED 33 is also connected to a voltage level Vss1 and receives the driving current. Once the driving current is being received, electric energy provided by the power line is transformed into light energy. With regard to the transistors mentioned above, amorphous Si (a-Si) thin film transistors (TFTs), high temperature poly-silicon TFTs, low temperature poly-silicon TFTs and single crystal silicon TFTs may be used. The first switch transistor 41, the first capacitor 43 and the first driving transistor 45 are disposed in the second sub-pixel area 32 to increase the area of the first OLED 33 as compared to that in the prior art. Therefore, brightness and lifetime of the OLED 33 in the first sub-pixel area 31 are can be improved.

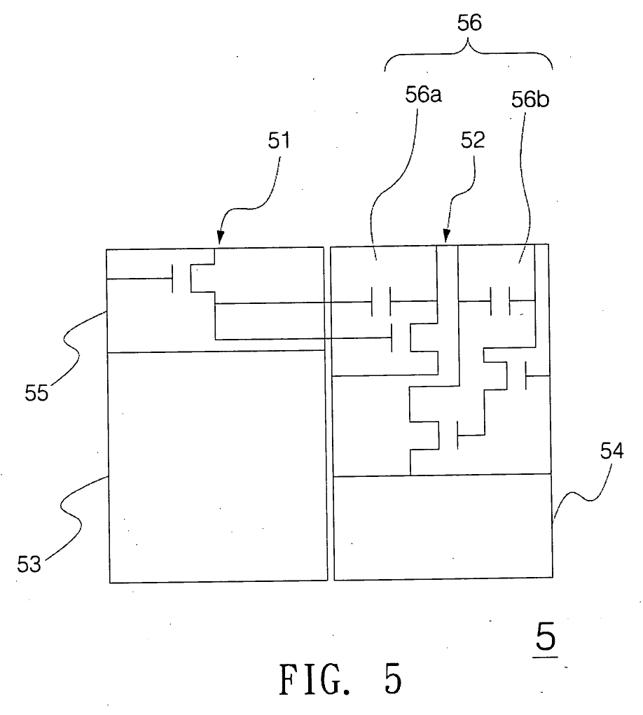

Referring to FIG. 5, a second embodiment of a pixel structure of an OLED display is depicted. The pixel structure 5 of the OLED display comprises a first sub-pixel area 51 and a second sub-pixel area 52. The first sub-pixel area 51 comprises a first OLED 53 and a first control circuit 55 having electronic components for controlling the first OLED 53. The second sub-pixel area 52 comprises a second OLED 54 and a second control circuit 56. The second control circuit 56 includes at least one electronic component for controlling the first OLED 53 and at least one electronic component for controlling the second OLED 54. For example, the second control circuit 56 disposed in the second sub-pixel area 52 comprises a first control circuit portion 56a for controlling the first OLED 53 and a second control circuit portion 56b for controlling the second OLED 54. In this embodiment, the light emission efficiency of the first OLED 53 can be lower than that of the second OLED 54. For example, the first OLED 53 can be a blue OLED and the second OLED 54 can be a red, green or white OLED. At least one of the electronic components for controlling the first OLED 53 is disposed in the second sub-pixel area 52. Thus, the area of the first OLED 53 can be increased compared to the conventional OLED. Therefore, brightness and lifetime of the first OLED 53 can be improved.

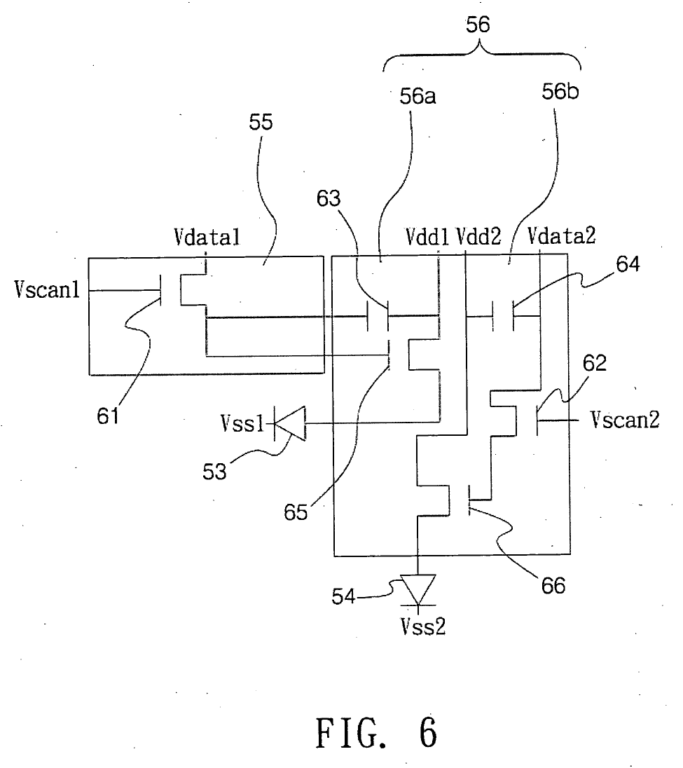

Referring to FIG. 6, the control circuits for the pixel 5 of the OLED display are depicted in greater detail. The first control circuit 55 comprises a first switch transistor 61. The second control circuit 56 comprises a first control circuit portion 56a including a first capacitor 63 and a first driving transistor 65, and a second control circuit portion 56b including a second switch transistor 62, a second capacitor 64 and a second driving transistor 66. The first control circuit 55 and the first control circuit portion 56a are used for controlling the first OLED 53. The second control circuit portion 56b is used for controlling the second OLED 54.

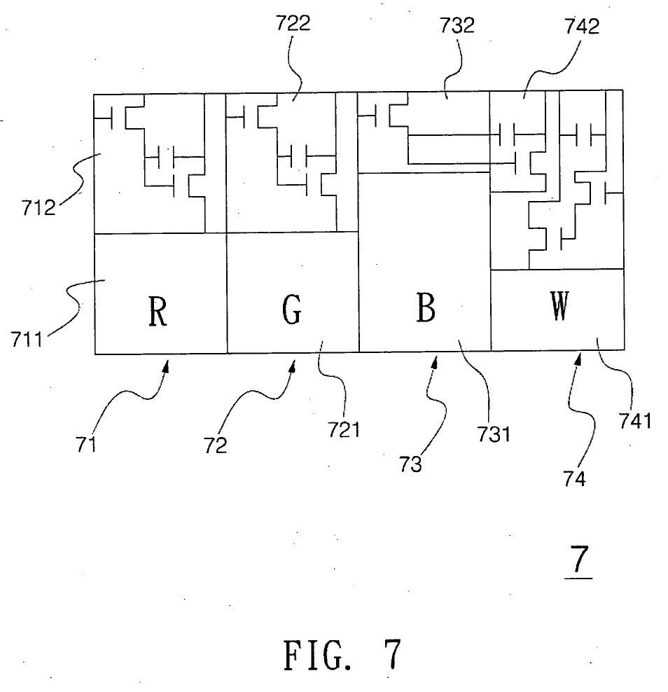

Referring to FIG. 7, a third embodiment of a pixel structure of an OLED display is depicted. The pixel structure 7 of the OLED display comprises an R sub-pixel area 71, a G sub-pixel area 72, a B sub-pixel area 73, and a W sub-pixel area 74. The R sub-pixel area 71 includes an R-OLED 711 and a control circuit 712. The G sub-pixel area 72 includes a G-OLED 721 and a control circuit 722. The B sub-pixel area 73 includes a B-OLED 731 and a control circuit 732. The W sub-pixel area 74 includes a W-OLED 741 and a control circuit 742.

According to this embodiment, the control circuit 712 includes all the electronic components, including a switch transistor, a driving transistor and a capacitor, for controlling the R-OLED 711. The control circuit 722 includes all the electronic components, including a switch transistor, a driving transistor and a capacitor, for controlling the G-OLED 721. However, the control circuit 732 only includes a portion of the electronic components for controlling the B-OLED 731. The other electronic components for controlling the B-OLED 731 are disposed in the W sub-pixel area 74. For example, as shown in FIG. 7, only one transistor for controlling the B-OLED 731 is disposed in the B sub-pixel area 73, while a transistor and a capacitor for controlling the B-OLED 731 are disposed in the W sub-pixel area 74. Thus, the W sub-pixel area 74 includes the control circuit 742 for controlling both the B-OLED 731 and the W-OLED 741.

Thus, the control circuit 732 disposed in the B sub-pixel area 73 accomodates the smallest area, and the control circuit 742 disposed in the W sub-pixel area 74 accomodates the largest area, among the four color sub-pixel areas. Generally, white OLED has the highest light emitting efficiency, and blue the lowest light emitting efficiency among the four color OLED materials. Therefore, by re-arrangment of the electronic components for controlling the B-OLED, e.g. disposing the electronic components for controlling the B-OLED in the white sub-pixel area, the B-OLED area is increased and the W-OLED area is decreased. Thus, the total light emitting efficiency of the B-OLED in the B sub-pixel area and the total light emitting efficiency of the W-OLED in the W sub-pixel area can be optimally adjusted.

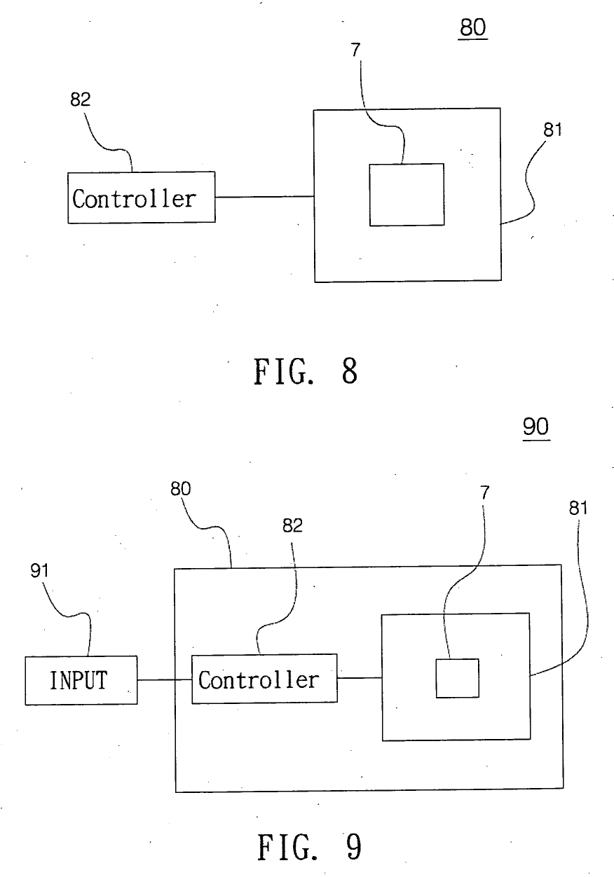

FIG. 8 shows an embodiment of a system implemented as a display device 80. Display device 80 comprises a display panel 81 incorporating a pixel structure, such as the pixel structure 7 as shown in FIG. 7. The display panel 81 can be coupled to a controller 82. The controller 82 can comprise source and gate driving circuits (not shown), controlling the display panel 81 for operation of the display device 80.

FIG. 9 is a schematic diagram illustrating an embodiment of a system implemented as an electronic device 90. Electronic device 90 incorporates a display device, such as the display device 80 shown in FIG. 8. An input 91 is coupled to the controller 82 of the display device 80. The input 91 can include a processor or the like to input image data to the controller 82 to render an image. The electronic device 90 may be a portable device such as a PDA, notebook computer, tablet computer, cellular phone, or a display monitor device, or a non-portable device such as a desktop computer, for example.

In conclusion, some embodiment of the present invention dispose the electrical components for controlling B-OLEDs to W sub-pixel areas. Thus, the area of a B-OLED, which has low light emitting efficiency, can be increased. Therefore, the total light emitting efficiency of the B-OLED in the B sub-pixel area can be increased.

While embodiments and applications of this invention have been shown and described, it would be apparent to those skilled in the art having the benefit of this disclosure that many more modifications than mentioned above are possible without departing from the inventive concepts herein.

What is claimed is:

1. A system for emitting light comprising:
a pixel structure of an organic light-emitting diode (OLED), the pixel structure comprising:
a first sub-pixel area including a first OLED; and
a second sub-pixel area including a second OLED and a second control circuit, wherein said second control circuit includes electronic components for controlling said first and second OLEDs.

2. The system as claimed in claim 1, wherein the first sub-pixel area includes no electronic components for controlling the first OLED.

3. A system for emitting light comprising:
pixel structure of an organic light emitting diode (OLED) device, comprising:
a first sub-pixel area including a first OLED;
a second sub-pixel area including a second OLED and a second control circuit, wherein said second control circuit includes electronic components for controlling the second OLED, and controlling any of the first OLED, the third OLED, the fourth OLED, or a combination of the first, third and fourth OLEDs;
a third sub-pixel area including a third OLED; and
a fourth sub-pixel area including a fourth OLED.

4. The system as claimed in claim 3, wherein the first sub-pixel area is a red sub-pixel area, green sub-pixel area, or blue sub-pixel area, and the second sub-pixel area is a white sub-pixel area.

5. The system as claimed in claim 3, wherein the first sub-pixel area includes no electronic components.

6. The system as claimed in claim 3, wherein said second control circuit includes electronic components for controlling the first and second OLEDs.

7. The system as claimed in claim 3, wherein said second control circuit includes electronic components for controlling the first, second, third, and fourth OLEDs.

8. The system as claimed in claim 3, wherein the first sub-pixel area further includes a first control circuit for controlling the first OLED.

9. The system as claimed in claim 8, wherein the first control circuit includes a switch transistor for controlling the first OLED, and wherein the second control circuit includes a capacitor and a driving transistor for controlling the first OLED.

10. The system as claimed in claim 9, wherein the first sub-pixel area is a red sub-pixel area, green sub-pixel area, or blue sub-pixel area, and the second sub-pixel area is a white sub-pixel area.

11. The system as claimed in claim 10, wherein the first sub-pixel area is a blue sub-pixel area.

12. The system as claimed in claim 3, comprising:
a first sub-pixel area including a first OLED and a first control circuit for controlling the first OLED;
a second sub-pixel area including a second OLED and a second control circuit, wherein said second control circuit includes electronic components for controlling the second OLED, and controlling any one of the first OLED, the third OLED, the fourth OLED, or a combination of the first, third and fourth OLEDs;
a third sub-pixel area including a third OLED and a third control circuit for controlling the third OLED; and
a fourth sub-pixel area including a fourth OLED and a fourth control circuit for controlling the fourth OLED.

13. The system as claimed in claim 12, wherein the first sub-pixel area is a red sub-pixel area, green sub-pixel area, or blue sub-pixel area, and the second sub-pixel area is a white sub-pixel area.

14. The system as claimed in claim 12, wherein said second control circuit includes electronic components for controlling the first and second OLEDs.

15. The system as claimed in claim 12, wherein said second control circuit includes electronic components for controlling the first, second, third, and fourth OLEDs.

16. The system as claimed in claim 1, wherein:
the system further comprises a display device; and
the pixel structure forms a portion of the display device.

17. The system as claimed in claim 16, wherein:
the system further comprises an electronic device comprising the display device.

18. The system as claimed in claim 16, further comprising a controller coupled to the display device to render an image to be displayed by the display device.

19. The system as claimed in claim 16, further comprising means for rendering an image to be displayed by the display device.

20. A system for emitting light comprising:
an electronic device having a display device, the display device being operative to display images;
the display device comprising pixels, at least one of which comprises:
a first sub-pixel area including a first OLED; and
a second sub-pixel area including a second OLED and a second control circuit, wherein said second control circuit includes electronic components for controlling said first and second OLEDs.
